(19) United States
(12) Patent Application Publication
(10) Pub. No.: US 2025/0162425 A1
(43) Pub. Date: May 22, 2025

(54) METHOD AND SYSTEM FOR REDUCING HARMONICS IN A RECTIFIED INCOMING WIRELESS POWER TRANSFER SIGNAL AT A RECEIVER OF AN ELECTRIC VEHICLE

(71) Applicant: Electreon Wireless Ltd., Beit Yanai (IL)

(72) Inventor: Hanan RUMBAK, Mazkeret Batya (IL)

(73) Assignee: Electreon Wireless Ltd., Beit Yanai (IL)

(21) Appl. No.: 19/036,245

(22) Filed: Jan. 24, 2025

Related U.S. Application Data
(63) Continuation-in-part of application No. 17/734,220, filed on May 2, 2022.
Application No. 17/734,220 is a continuation of application No. 16/655,395, filed on Oct. 17, 2019, now Pat. No. 11,318,845.
(60) Provisional application No. 63/624,516, filed on Jan. 24, 2024.

(30) Foreign Application Priority Data
Dec. 31, 2013 (GB) GB1323160.0

(51) Int. Cl. B60L 5/00; B60L 53/12; B60M 1/10; B60M 3/06; B60M 7/00; H01F 38/14; H02J 50/12; H03H 7/38

(52) U.S. Cl. CPC B60L 5/005; B60L 53/12; B60M 1/10; B60M 3/06; B60M 7/003; H01F 38/14; H02J 50/12; H03H 7/38; B60L 2210/30; Y02T 10/70; Y02T 10/7072; Y02T 90/12; Y02T 90/16

(57) ABSTRACT

A system and method for reducing harmonics in a rectified incoming wireless power transfer signal at a receiver of an electrical vehicle are provided herein. The electrical vehicle receiver shall be equipped with a two-stage filter which shall reduce the harmonics post rectifying of the alternating current inducted at the receiver coils. Advantageously, using a specially designed capacitor, an effective reduction of the harmonics is achieved for power efficiency and electromagnetic compliance (EMC). The design is challenging due to the high amperage and frequency range of the alternating current.

### CROSS REFERENCE TO RELATED APPLICATIONS

This Application claims priority from U.S. Provisional Patent Application No. 63/624,516 filed on Jan. 24, 2024 and is also a Continuation-in-Part Application of U.S. patent application Ser. No. 17/734,220 which was filed on May 2, 2022 as a Continuation Application of U.S. patent application Ser. No. 16/655,395, which was filed on Oct. 17, 2019 as a Continuation Application of U.S. patent application Ser. No. 15/198,844, which was filed on Jun. 30, 2016 as a Continuation-in-Part Application of PCT Patent Application No. PCT/IL2014/051140, which was filed on Dec. 31, 2014 claiming priority from GB Patent Application No. GB1323160.0, filed on Dec. 31, 2013, all of which are incorporated herein by reference in their entireties.

### FIELD OF THE INVENTION

The present invention relates generally to wireless power transmission in electric vehicles and more specifically to reducing harmonics in a rectified incoming wireless power transfer signal at a receiver of an electric vehicle.

### BACKGROUND OF THE INVENTION

Prior to setting forth the background of the invention, it would be advantageous to provide some term definitions as follows:

The term ‘electric vehicle’ or EV refers generally to a vehicle powered solely, or in part, by electrical energy stored (e.g., chemically) in a battery, or the like. In the present context, an ‘electric vehicle’ moreover has provision for receiving (e.g., at coils disposed of the underside of the vehicle) a wirelessly induced electromotive force (i.e., voltage) that may be stored, or otherwise utilized to recharge the battery. For an electromagnetically induced voltage to occur, the vehicle (i.e., the ‘conductor’) may be moving relative to a magnetic field which is, for example, projected about the road upon which the vehicle is travelling. Alternatively, the magnetic field may be periodically varied (e.g., through use of alternating current) thereby inducing a voltage at the vehicle.

The term ‘road section’ refers generally to a portion of, for example, a highway or motorway which has been modified to comprise a medium for wirelessly transmitting power (i.e., a ‘power transmitter’). This may mean that the road comprises a plurality of coils embedded beneath the surface of the road section which are operable to emit a magnetic field. In typical arrangements, the medium (coils) may be connected to an alternating current source, e.g. an electrical grid, and may generate a varying magnetic field, thereby inducing a voltage in any proximate conductor.

The term ‘ground assembly” refers generally to a portion of, for example, a road, a highway or motorway which has been modified to comprise a medium for wirelessly transmitting power (i.e., a ‘power transmitter’). This may mean that the road comprises a plurality of coils embedded beneath the surface of the road section which are operable to emit a magnetic field. In typical arrangements, the medium (coils) may be connected to an alternating current source, e.g. an electrical grid, and may generate a varying magnetic field, thereby inducing a voltage in any proximate conductor.

The term ‘vehicle assembly” refers generally to circuitry on board of the electric vehicle which include a receiver to receive the power transmitted from the ground assembly, an energy regulator, as well as other circuitries as needed to ensure the battery of the electric vehicle and then the motor of the electric vehicle receive the energy per their requirements.

FIG. 1 is a block diagram illustrating a prior art wireless power transmission system 100. Wireless power transmission system 100 may include a plurality of electric vehicles 150 comprising an attached power receiver, for example, to an underside of the vehicle. The plurality of electric vehicles may further travel upon a road section 101 having one or more power transmitters 120 disposed, for example, underneath the surface of the road section and fed by power converter 122 connected to an electrical grid. In some embodiments, each power receiver and power transmitter may comprise one or more wound or looped coils coupled, for example, to an alternating current source. In some arrangements, these coils may be operable to emit a static or varying magnetic field into a vicinity about the coils, for example around the road section or portions thereof. As each electric vehicle travels along road section 101, a magnetic field formed by power transmitters in road section 101 induces a voltage in each power receiver and is stored and/or converted by the electric vehicle into, for example, chemical energy in a battery. In alternative embodiments, the induced energy may be immediately used by an engine of the electric vehicle without storage.

On the electric vehicle side, the power receiver includes a rectifier. Since the signal which is being rectified is approximately 85 kHz and power of approximately 70 kW then high harmonics are created which are very difficult to attenuate.

### SUMMARY OF THE PRESENT INVENTION

The present invention provides a system and method for reducing harmonics in a rectified incoming wireless power transfer signal at a receiver of an electric vehicle. The electric vehicle receiver shall be equipped with a two-stage filter which shall reduce the harmonics post rectifying of the alternating current inducted at the receiver coils. Advantageously, using a specially designed capacitor, an effective reduction of the harmonics is achieved for power efficiency and electromagnetic compliance (EMC). The design is challenging due to the high amperage and frequency range of the alternating current.

These and other advantages of the present invention are set forth in detail in the following description.

### BRIEF DESCRIPTION OF THE DRAWINGS

For a better understanding of the invention and in order to show how it may be implemented, references are made, purely by way of example, to the accompanying drawings in which like numerals designate corresponding elements or sections. In the accompanying drawings:

FIG. 1 is a block diagram showing wireless power transmission system for an electric vehicle on a road in accordance with the prior art;

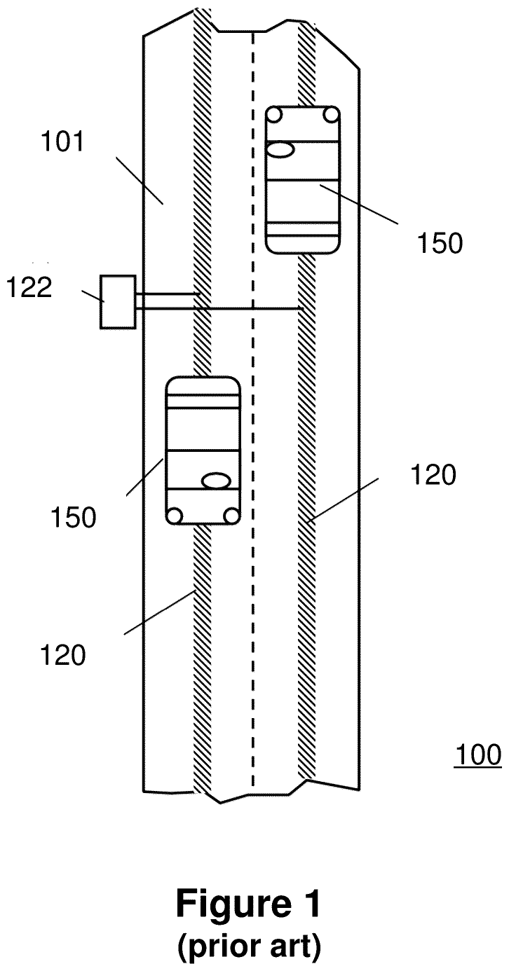

FIG. 2 is a circuit diagram in accordance with some embodiments of the present invention;

FIG. 3 is another circuit diagram in accordance with some embodiments of the present invention; and

FIG. 4 is a graph diagram in accordance with some embodiments of the present invention.

It will be appreciated that for simplicity and clarity of illustration, elements shown in the figures have not necessarily been drawn to scale. For example, the dimensions of some of the elements may be exaggerated relative to other elements for clarity. Further, where considered appropriate, reference numerals may be repeated among the figures to indicate corresponding or analogous elements.

### DETAILED DESCRIPTION OF THE INVENTION

With specific reference now to the drawings in detail, it is stressed that the particulars shown are for the purpose of example and solely for discussing the preferred embodiments of the present invention and are presented in the cause of providing what is believed to be the most useful and readily understood description of the principles and conceptual aspects of the invention. In this regard, no attempt is made to show structural details of the invention in more detail than is necessary for a fundamental understanding of the invention. The description taken with the drawings makes apparent to those skilled in the art how the several forms of the invention may be embodied in practice.

Before explaining the embodiments of the invention in detail, it is to be understood that the invention is not limited in its application to the details of construction and the arrangement of the components set forth in the following descriptions or illustrated in the drawings. The invention is applicable to other embodiments and may be practiced or carried out in various ways. Also, it is to be understood that the phraseology and terminology employed herein is for the purpose of description and should not be regarded as limiting.

According to some embodiments of the present invention, the vehicle assembly (the power receiver) may be placed on board an electric vehicle and may include receiver coils which may be coupled to transmitter coils. Receiver coils may feed the input of a rectifier which is configured to rectify the alternating current into direct current. The rectifier in turn feeds the input of a two-stage direct current (DC) filter which reduces the harmonies of the power signal passing through it. The output of DC filter is also effectively the output of vehicle assembly which may feed the EV battery which in turn feeds the motor of the EV.

According to some embodiments of the present invention, a vehicle assembly for operating with a ground assembly as part of a wireless power transmission system for electric vehicles, is provided herein. The vehicle assembly may include: a resonance circuitry connected to power receiving coils, couplable with transmission coils of the ground assembly; a rectifier connected to the resonance circuitry and configured to rectify alternating current coming from the resonance circuity, yielding a rectified signal; a pre-filter connected to an output of the rectifier and configured to attenuate harmonics of order 2 to 10 of the rectified signal, yielding a pre-filtered signal; and a filter connected to an output of the pre-filter and configured to attenuate harmonics of order higher than 10 of the pre-filtered signal, yielding a filtered signal.

According to some embodiments of the present invention, the resonance circuitry may be capable of operating in a frequency range of 80 kHz to 90 kHz.

According to some embodiments of the present invention, the vehicle assembly may be capable of handling a power up to approximately 70 kW.

According to some embodiments of the present invention, the resonance circuitry may have a fundamental frequency of approximately 85 kHz.

According to some embodiments of the present invention, the vehicle assembly may be capable of handling a voltage up to approximately 1000V.

According to some embodiments of the present invention, the pre-filter may include an LC circuitry having a capacitor connected in parallel and an inductor connected in series with the capacitor having a capacitance value of approximately 0.65 uF and the inductor having an inductance value of approximately 5 uH.

According to some embodiments of the present invention, the output of the filter may be coupled to a battery of an electric vehicle.

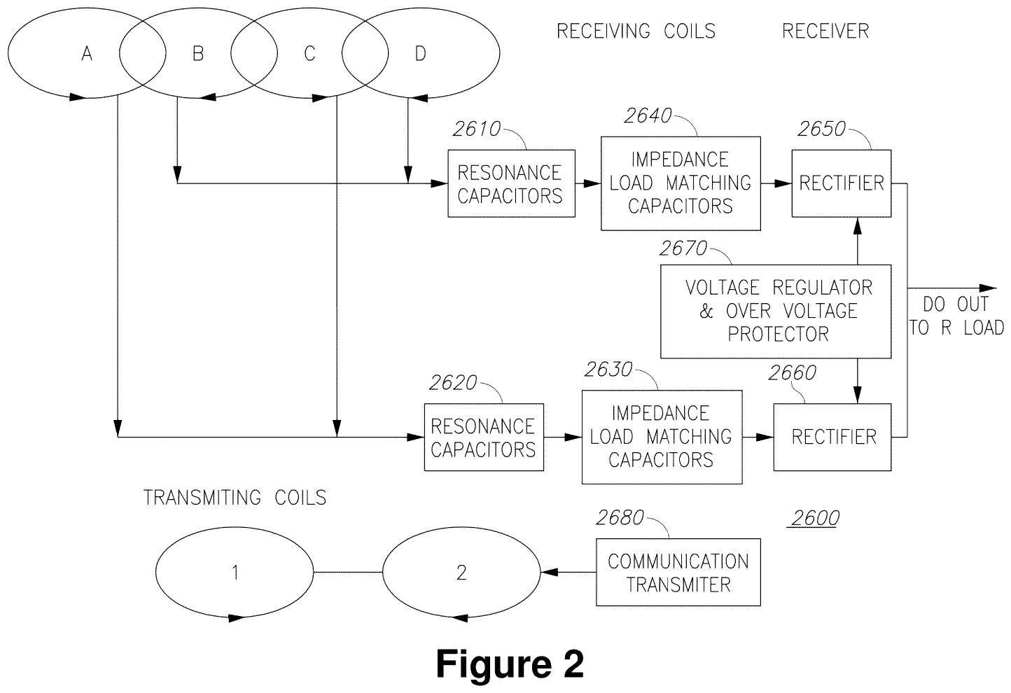

Following below is a more detailed description and non-limiting example of an implementation of some embodiments of the present invention. FIG. 2 is a diagram illustrating aspects relating powering aspect on the receiver side according to some embodiments of the present invention. Power transmitting coils 1 and 2 are instructed by communication module on the road side 2680 to provide energy to respective power receiving coils A, B, C, and D (resonance with 1 and 2 only occur two at a time, A and C, and B and D). It is clear that a use of 3 coils such as a pair of coils and a single coil can also be implemented.

The alternating current is at a frequency of approximately 80-90 KHz, being the preferred resonance frequency of the inductance circuits at the power transmitting and power receiving segments.

Each pair of coils A-C and B-D is then fed into respective resonance capacitors 2620 and 2610 respectively and then to impedance load matching capacitors 2630 and 2640, to rectifiers 2660 and 2650 and eventually to voltage regulator 2670 which outputs direct current to the load being the electric motor of the vehicle (not shown).

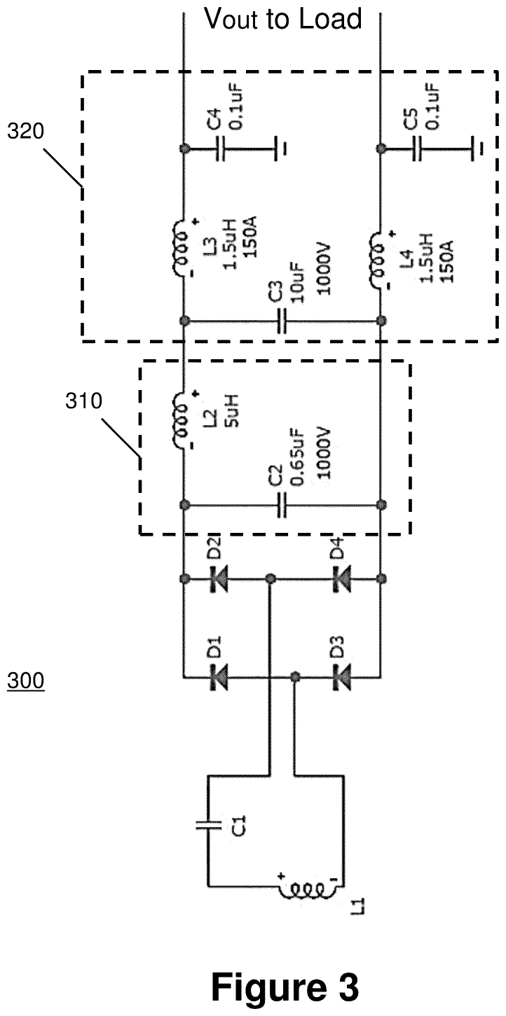

FIG. 3 is a circuit diagram illustrating a receiver 300 in accordance with some embodiments of the present invention. L1 and C1 form the LC resonance circuit which is coupled with the transmitter coils (not shown here). Diodes D1-D4 form the rectifier. Since receiver 300 is designed to handle power up to approximately 70 kW and the AC signal which is being rectified is approximately at 80 kHz to 90 kHz. After rectifying (detection), the clean sine becomes a distorted wave that contains high harmonics which are undesirable.

The inventor of the present invention suggests adding a pre-filter stage 310 with C2 and L2 with values that are carefully selected given the high power current that flows through the receiver. The capacitor C2 is a special capacitor that sits on a heat sink and is cooled by air cooling, The objective of pre-filter stage 310 is to function is to attenuate higher harmonics, 2 to 10. The value of C2 should be approximately 0.65 uF and L2 should be approximately 5 uH. These values have been carefully selected during simulation in order to provide optimal results for reducing number of elements, physical dimensions and cost.

The receiver further has a filter stage 320 (which is typical low pass filter) which includes capacitors C4 and C5 and inductors L4 and L3. Stage 320 is configured to attenuate harmonics over 10 before entering the load (the electric motor).

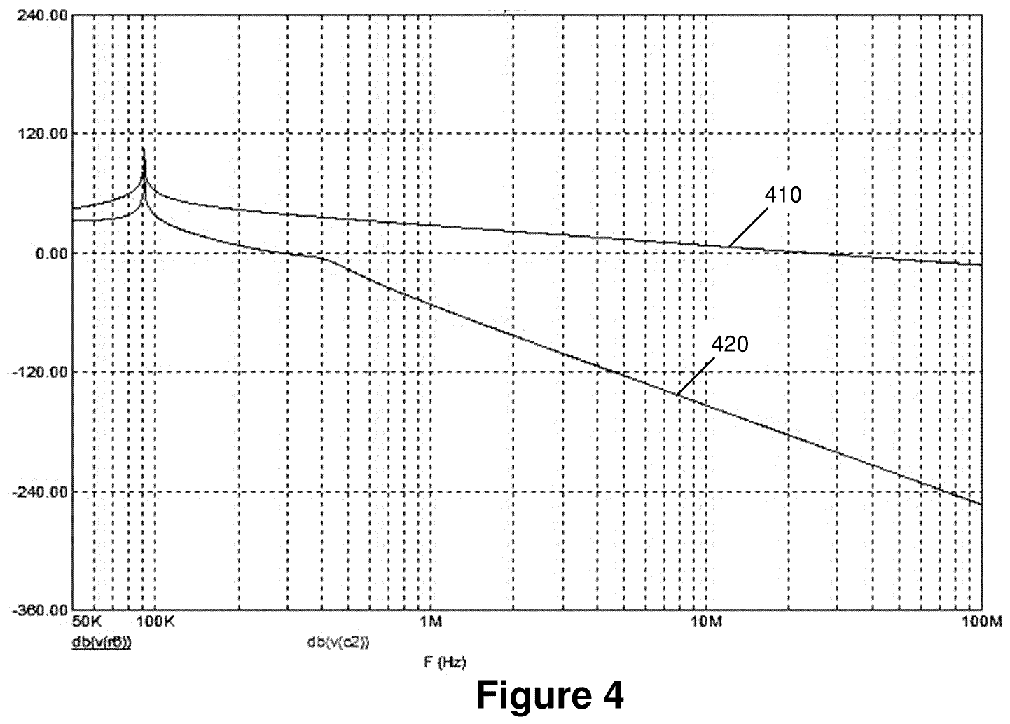

FIG. 4 is a logarithmic graph showing the voltage over capacitor C2 (line 410) and voltage over the load (line 420) as a function of the frequency (a range of 50 kHz to 100 MHz is shown) of pre filter stage 310 of FIG. 3.

The fundamental working frequency in this simulation is around 85 kHz, after the rectifying, the frequency is doubled and therefore the pole that appears on the graphs (90 khz) does not actually exist in this circuit, the working frequency will therefore be 170 khz and therefore the harmonics must also be addressed at higher frequencies.

The graph illustrates that the effectiveness of pre-filter stage 310 of FIG. 3 in attenuating harmonics 2-10.

It should be understood that value of the capacitor C2 and the coil L2 are critical. Higher values will be physically large and expensive whereas smaller values might bring the pole closer to the operating frequency and therefore their values have been carefully selected. The selected values have been identified by the inventors of the present invention as providing significantly better results over any other tested capacitors and

The aforementioned flowchart and diagrams illustrate the architecture, functionality, and operation of possible implementations of systems, methods, and computer program products according to various embodiments of the present invention. In this regard, each portion in the flowchart or portion diagrams may represent a module, segment, or portion of code, which comprises one or more executable instructions for implementing the specified logical function(s). It should also be noted that, in some alternative implementations, the functions noted in the portion may occur out of the order noted in the figures. For example, two portions shown in succession may, in fact, be executed substantially concurrently, or the portions may sometimes be executed in the reverse order, depending upon the functionality involved, It will also be noted that each portion of the portion diagrams and/or flowchart illustration, and combinations of portions in the portion diagrams and/or flowchart illustration, can be implemented by special purpose hardware-based systems that perform the specified functions or acts, or combinations of special purpose hardware and computer instructions.

As will be appreciated by one skilled in the art, aspects of the present invention may be embodied as a system or an apparatus. Accordingly, aspects of the present invention may take the form of an entirely hardware embodiment or an embodiment combining software and hardware aspects that may all generally be referred to herein as a “circuit”, “module” or “system”.

The aforementioned figures illustrate the architecture, functionality, and operation of possible implementations of systems and apparatus according to various embodiments of the present invention. Where referred to in the above description, an embodiment is an example or implementation of the invention. The various appearances of “one embodiment,” “an embodiment” or “some embodiments” do not necessarily all refer to the same embodiments.

Although various features of the invention may be described in the context of a single embodiment, the features may also be provided separately or in any suitable combination. Conversely, although the invention may be described herein in the context of separate embodiments for clarity, the invention may also be implemented in a single embodiment.

Reference in the specification to “some embodiments”, “an embodiment”, “one embodiment” or “other embodiments” means that a particular feature, structure, or characteristic described in connection with the embodiments is included in at least some embodiments, but not necessarily all embodiments, of the inventions. It will further be recognized that the aspects of the invention described hereinabove may be combined or otherwise coexist in embodiments of the invention.

It is to be understood that the phraseology and terminology employed herein is not to be construed as limiting and are for descriptive purpose only.

The principles and uses of the teachings of the present invention may be better understood with reference to the accompanying description, figures and examples.

It is to be understood that the details set forth herein do not construe a limitation to an application of the invention.

Furthermore, it is to be understood that the invention can be carried out or practiced in various ways and that the invention can be implemented in embodiments other than the ones outlined in the description above.

It is to be understood that the terms “including”, “comprising”, “consisting of” and grammatical variants thereof do not preclude the addition of one or more components, features, steps, or integers or groups thereof and that the terms are to be construed as specifying components, features, steps or integers.

If the specification or claims refer to “an additional” element, that does not preclude there being more than one of the additional element.

It is to be understood that where the claims or specification refer to “a” or “an” element, such reference is not construed that there is only one of that element.

It is to be understood that where the specification states that a component, feature, structure, or characteristic “may”, “might”, “can” or “could” be included, that particular component, feature, structure, or characteristic is not required to be included.

Where applicable, although state diagrams, flow diagrams or both may be used to describe embodiments, the invention is not limited to those diagrams or to the corresponding descriptions. For example, flow need not move through each illustrated box or state, or in exactly the same order as illustrated and described.

Methods of the present invention may be implemented by performing or completing manually, automatically, or a combination thereof, selected steps or tasks.

The term “method” may refer to manners, means, techniques and procedures for accomplishing a given task including, but not limited to, those manners, means, techniques and procedures either known to, or readily developed from known manners, means, techniques and procedures by practitioners of the art to which the invention belongs.

The descriptions, examples and materials presented in the claims and the specification are not to be construed as limiting but rather as illustrative only.

Meanings of technical and scientific terms used herein are to be commonly understood as by one of ordinary skill in the art to which the invention belongs, unless otherwise defined.

The present invention may be implemented in the testing or practice with materials equivalent or similar to those described herein.

While the invention has been described with respect to a limited number of embodiments, these should not be construed as limitations on the scope of the invention, but rather as exemplifications of some of the preferred embodiments. Other or equivalent variations, modifications, and applications are also within the scope of the invention. Accordingly, the scope of the invention should not be limited by what has thus far been described, but by the appended claims and their legal equivalents.

1. A vehicle assembly for operating with a ground assembly as part of a wireless power transmission system for electric vehicles, the vehicle assembly comprising:
a resonance circuitry connected to power receiving coils, couplable with transmission coils of the ground assembly;
a rectifier connected to the resonance circuitry and configured to rectify alternating current coming from the resonance circuity, yielding a rectified signal;
a pre-filter connected to an output of the rectifier and configured to attenuate harmonics of order 2 to 10 of the rectified signal, yielding a pre-filtered signal; and
a filter connected to an output of the pre-filter and configured to attenuate harmonics of order higher than 10 of the pre-filtered signal, yielding a filtered signal.

2. The vehicle assembly according to claim 1, wherein the resonance circuitry is capable of operating in a frequency range of 80 kHz to 90 kHz.

3. The vehicle assembly according to claim 2, wherein the vehicle assembly is capable of handling a power up to approximately 70 kW.

4. The vehicle assembly according to claim 3, wherein the resonance circuitry with a fundamental frequency of approximately 85 kHz.

5. The vehicle assembly according to claim 4, wherein the vehicle assembly is capable of handling a voltage up to approximately 1000V.

6. The vehicle assembly according to claim 5, wherein the pre-filter comprises an LC circuitry having a capacitor connected in parallel and an inductor connected in series, with the capacitor having a capacitance value of approximately 0.65 uF and the inductor having an inductance value of approximately 5 uH.

7. The vehicle assembly according to claim 6, wherein an output of the filter is couplable to a battery of an electric vehicle.

8. A method for reducing harmonics in a rectified incoming wireless power transfer signal at a vehicle assembly for operating with a ground assembly as part of a wireless power transmission system for electric vehicles, the method comprising:
rectifying, by a rectifier, an alternating current coming from a resonance circuitry connected to power receiving coils, couplable with transmission coils of the ground assembly, yielding a rectified signal;
attenuating, by a pre-filter, harmonics of order 2 to 10 of the rectified signal, yielding a pre-filtered signal; and
attenuating, by a filter, harmonics of order higher than 10 of the pre-filtered signal, yielding a filtered signal.

9. The method according to claim 8, wherein the resonance circuitry is capable of operating in a frequency range of 80 kHz to 90 kHz.

10. The method according to claim 9, wherein the vehicle assembly is capable of handling a power up to approximately 70 kW.

11. The method according to claim 10, wherein the resonance circuitry with a fundamental frequency of approximately 85 kHz.

12. The method according to claim 11, wherein the vehicle assembly is capable of handling a voltage up to approximately 1000V.

13. The method according to claim 12, wherein the pre-filter comprises an LC circuitry having a capacitor connected in parallel and an inductor connected in series with the capacitor having a capacitance value of approximately 0.65 uF and the inductor having an inductance value of approximately 5 uH.

14. The method according to claim 13, wherein an output of the filter is couplable to a battery of an electric vehicle.
